(19) United States
(12) Patent Application Publication
(10) Pub. No.: US 2007/0059942 A1
(43) Pub. Date: Mar. 15, 2007

(54) PLASMA CVD PROCESS FOR MANUFACTURING MULTILAYER ANTI-REFLECTION COATINGS

(75) Inventors: Chen Ze Hu, Jhonghe City, Taipei County (TW); Shen Yin Tsai, Tainan (TW)

Correspondence Address: PAI PATENT & TRADEMARK LAW FIRM, 1001 FOURTH AVENUE, SUITE 3200, SEATTLE, WA, 98154, US

(73) Assignee: CHI LIN TECHNOLOGY CO., LTD., Tainan County (TW)

(21) Appl. No.: 11/162,425

(22) Filed: Sep. 9, 2005

(51) Int. Cl. H01L 21/473

(52) U.S. Cl. 438/763; 438/788; 438/798; 438/785

(57) ABSTRACT

A plasma chemical vapor deposition (CVD) process for the production of a multilayer anti-reflection coating on substrates (especially on substrates with curved or uneven surface) is disclosed. The CVD process utilizes free radical plasma to form the multilayer anti-reflection coating in order to achieve necessary coating thickness uniformity.

### BACKGROUND OF THE INVENTION

1. Field of the Invention

This invention relates to a plasma chemical vapor deposition (CVD) process for the production of multilayer optical coatings, such as anti-reflective or anti-glare coating on substrates, especially on substrates with curved or uneven surface.

2. Description of the Related Art

Recently, anti-reflection coatings have been used for a myriad of purposes. Anti-reflection coatings are most commonly used on windows, mirrors, and an assortment of display applications which includes television screens and computer monitor screens to minimize reflective “glare.”

The simplest anti-reflection coating is a single layer of a transparent material having a refractive index less than that of a substrate on which it is disposed. The optical thickness of such a layer may be about one-quarter wavelength at a chosen wavelength in the visible spectrum. A single layer coating produces a minimum reflection value at the chosen wavelength. At all other wavelengths the reflection is higher than the minimum but less than the reflection of an uncoated substrate.

Multilayer anti-reflection coatings are typically made by depositing two or more layers of transparent dielectric materials on a substrate. Multilayer anti-reflection coatings may yield reflection values of less than 0.25 percent over the visible spectrum. U.S. Pat. No. 5,170,291 discloses a four-layer anti-reflection coating where DC reactive sputtering has been suggested as a preferred method of deposition. U.S. Pat. No. 5,579,162 discloses a multi-layer anti-reflection coating utilizing DC reactive sputtering as a preferred method of deposition for temperature sensitive substrates. In addition, it is also disclosed how to produce the anti-reflection coating using E-beam evaporation or sol-gel method. However, these methods are not suitable for substrates with curved or uneven surface because the necessary coating thickness uniformity cannot be achieved.

There are a number of methods that have been developed to deposit a scratch resistant coating to lenses through a plasma CVD process with gases from oxygen and silicone or silane precursors. Information relevant to attempts to the production of coatings using a plasma CVD process can be found in U.S. Pat. Nos. 4,927,704 and 4,991,542. Another similar method for producing low friction or slippery coating is described in U.S. Pat. No. 5,463,010. However, it is neither disclosed nor suggested how to produce the anti-reflection coating using a plasma CVD process. In addition, no solution is given as to how the necessary coating thickness uniformity can be achieved with curved or uneven substrates using a plasma CVD process.

### SUMMARY OF THE INVENTION

It is therefore an object of the present invention to provide a plasma chemical vapor deposition (CVD) process for the production of multilayer anti-reflection coatings on substrates (especially on substrates with curved or uneven surface), which can achieve a necessary coating thickness uniformity.

Using the plasma CVD process in thin film deposition has several unique advantages over other coating techniques. Since plasma CVD process is a dry coating process, it will not change the bulk of raw materials but will change only the surface properties. Plasma CVD is able to deposit chemicals that are vaporizable in the gas phase and condensable onto the substrate. The plasma CVD process is a truly thin film deposition process and it can precisely control the chemical composition of the coating and the deposition thickness on the order of nm to μm.

In accordance with the above listed and other objects, we disclose a process for manufacturing an anti-reflection coating of a predetermined thickness and uniformity on a substrate surface. The process includes the following steps: (a) placing the substrate in a reaction chamber; (b) introducing a first reactive gas mixture into the reaction chamber; (c) generating a first free radical plasma within the reaction chamber by activating the first reactive gas mixture thereby forming the first layer on the substrate; (d) introducing a second reactive gas mixture into the reaction chamber; and (e) generating a second free radical plasma within the reaction chamber by activating the second reactive gas mixture thereby forming the second layer on the substrate.

Note that the CVD process of the present invention utilizes free radical plasma to form the anti-reflection coating. Since free radicals (e.g., species bearing an unpaired electron) have no charge and are electrically neutral, the distribution of the free radicals is free from the electric field required for maintaining the plasma. Therefore, the free radical plasma distributes uniformly around the substrate such that the process of the present invention can achieve the necessary coating thickness uniformity in nanoscale even though the substrate has a curved or uneven surface.

### BRIEF DESCRIPTION OF THE DRAWINGS

These and other features, aspects, and advantages of the present invention will be more fully understood by reading the following detailed description of the preferred embodiment, with reference made to the accompanying drawings as follows:

FIG. 1 illustrates a conceptual view of a chemical vapor deposition (CVD) system suitable for use with the present invention;

FIG. 2 illustrates deposition of plasma CVD generated free radicals onto substrate;

FIG. 3 is a cross-sectional view showing an anti-reflection coating formed on a curved substrate according to one embodiment of the present invention;

FIG. 4 is a cross-sectional view showing a portion of the anti-reflection coating in FIG. 3 on an enlarged scale;

FIG. 5 is a cross-sectional view showing an anti-reflection coating with top diffuser feature formed on a curved substrate according to another embodiment of the present invention; and

FIG. 6 is a cross-sectional view showing a portion of the anti-reflection coating with top diffuser feature in FIG. 5 on an enlarged scale.

### DETAILED DESCRIPTION OF THE PREFERRED EMBODIMENT

The present invention is directed to a plasma chemical vapor deposition (CVD) process utilizing free radical to form the multilayer anti-reflection coatings, especially on substrates with curved or uneven surface, in order to achieve necessary coating thickness uniformity.

An anti-reflection coating according to the present invention is a composite of stacks of high refractive index/low refractive index plasma CVD thin films which are substantially transparent to visible light.

If a hetero-structure is adopted, the anti-reflective coating of the present invention preferably includes alternate layers of a dielectric material, such as silicon dioxide, with an index of refraction lower than the substrate on which it is formed and a metal oxide (e.g., titanium dioxide, tin oxide, indium oxide, zinc oxide, tin-doped indium oxide and zinc-tin oxide) with a reasonably high refractive index. If a homo-structure of anti-reflective coating is adopted, a controllable refractive index precursor, such as titanium tetrachloride or HMDSO (hexamethyldisiloxane) is mixed with a reactive oxygen or water vapor to deposit a stack of layers of TiOₓ or SiOₓ onto the substrate. Each layer's refractive index is determined by the oxygen content of the TiO_{x.} or SiOₓ. The higher the x, the closer is the refractive index to that of pure oxide.

The reaction of titanium tetrachloride and water vapor can be illustrated by:
TiCl₄(g)+2H₂O(g)→TiOₓ+4HCl(g)(ideal), x=1˜2

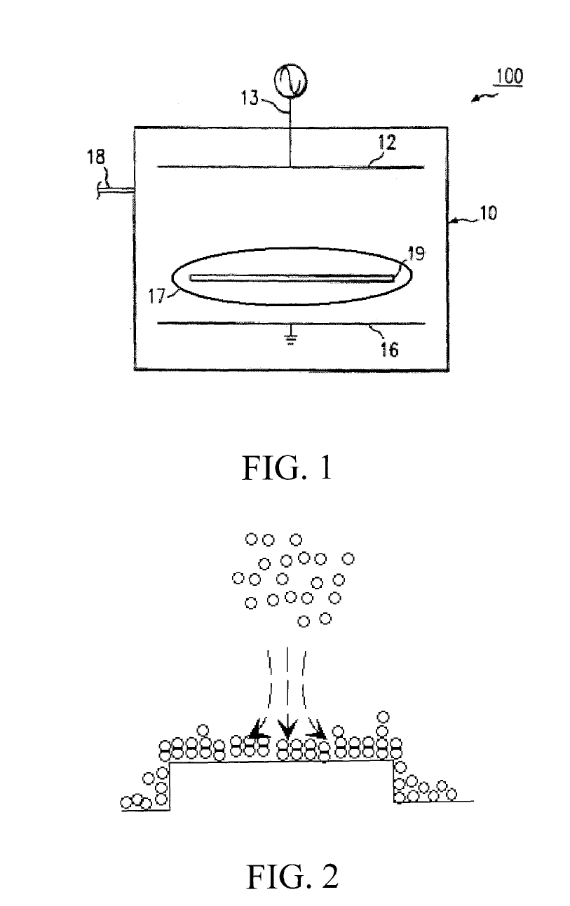

FIG. 1 illustrates a conceptual view of a chemical vapor deposition (CVD) system 100 suitable for use with the present invention. It could be understood that both batch and in-line plasma CVD reactors are suitable for use with the present invention. As shown in FIG. 1, reactive gas mixtures are introduced into a reaction chamber 10 via an inlet 18. An RF powered electrode 12 is connected to an RF power source 13, which can, for example, generate 150 watts at 13.56 megahertz. After the reactive gas mixture is introduced into the reaction chamber 10, the reactive gas mixture is activated through excitation by radio frequency (RF) energy from the power source 13 to produce free radical plasma 17 between electrodes 12 and 16 and is in contact with a substrate 19 which is held in a substrate holder within the reaction chamber 10 (not shown). Specifically, when the RF power source 13 is applied to the electrodes 12 and 16, electrons are forced to flow from one electrode to the other. To enhance the flow of electrons, the pressure within the reaction chamber 10 can be reduced to less than 500 mtorr. As the electrons traverse the gap between the electrodes, the electrons accelerate. During the acceleration, collisions of the electrons occur with the reactive gas mixture used by the present invention. The collisions cause the dissociation necessary for activating the reactive gas mixture. Accordingly, this process of activation by dissociation of the reactive gas mixture produces a plasma consisting essentially of free radicals. Since free radicals (e.g., species bearing an unpaired electron) have no charge and are electrically neutral, the distribution of the free radicals is free from the electric field required for maintaining the plasma. Therefore, the free radical plasma 17 distributes uniformly around the substrate 19 such that the process of the present invention can achieve the necessary coating thickness uniformity in nanoscale even though the substrate 19 has a curved or uneven surface. FIG. 2 illustrates the free radicals are evenly distributed onto the substrate surface.

The process of present invention is especially suitable for forming multilayer anti-reflection coatings on the interior side of dome shaped substrates or glass substrates with some fine corrugated (concave or convex) portions formed thereon. The concave or convex portions typically have a triangular cross section. If two surfaces of the substrate are to be coated, both surfaces can be coated simultaneously as illustrated above. However, if only one surface of the substrate is to be coated, the other surface should be shielded from undesired coating.

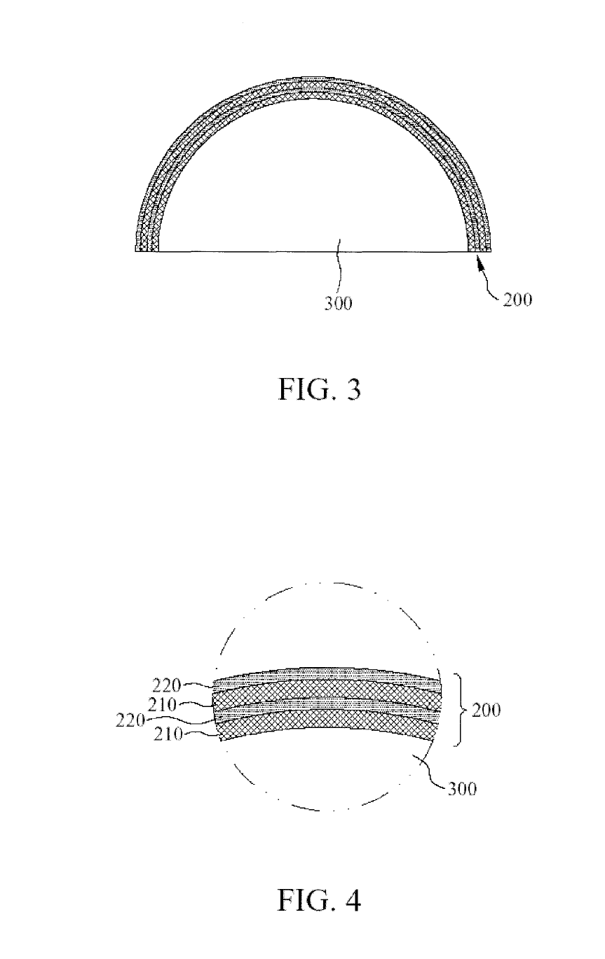

FIG. 3 and FIG. 4 illustrate an anti-reflection coating 200 formed on a curved substrate 300 according to one embodiment of the present invention. The anti-reflection coating 200 includes alternate layers of silicon dioxide 210 and titanium dioxide 220. Though only four layers are illustrated in FIG. 3 and FIG. 4, an anti-reflection coating for use with the invention can include any number of layers, depending on the application. With this coating, reflection is typically reduced to less than one percent. In this embodiment, two kinds of reactive gas mixtures are introduced into the reaction chamber 10 alternately and activated to form the anti-reflection coating. Specifically, the silicon dioxide layer may be produced from a first reactive gas mixture including gaseous oxygen (or water vapor) and a silicon-source precursor such as siloxane (e.g., hexamethyldisiloxane (HMDSO)) or silane (e.g., diethylsilane or tetraethoxysilane (TEOS). The titanium dioxide may be produced from a second reactive gas mixture including gaseous water and a titanium-source precursor such as titanium tetrachloride or titanium sulfate. Alternatively, the titanium dioxide layer may be replaced by a tin oxide layer which may be produced from another reactive gas mixture including gaseous water and a tin-source precursor such as tin tetrachloride. Additionally, a non-reactive carrier gas may also be used during deposition. Suitable inert gases include the Noble gases, such as neon, helium and argon.

In addition, different gas ratio in the plasma CVD process for a selected layer may produce different refractive index values. For example, the refractive index of the silicon dioxide layer is proportional to the ratio of the gaseous oxygen (or water vapor) to the silicon-source precursor in the first reactive gas mixture. The refractive index of the titanium dioxide layer is proportional to the ratio of the gaseous water to the titanium-source precursor in the second reactive gas mixture.

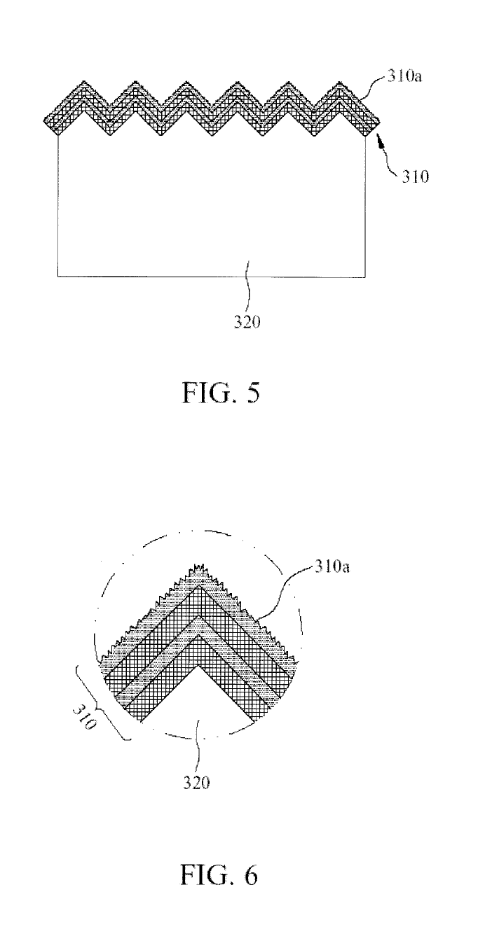

FIG. 5 and FIG. 6 illustrate an anti-reflection coating 310 with top diffuser feature formed on a corrugated substrate 320 with a sawtoothed profile according to one embodiment of the present invention. The anti-reflection coating 310 is substantially identical to the anti-reflection coating 200 of FIG. 4 with the exception that the anti-reflection coating 310 is further subjected to an anti-glare treatment to form a nanostructured surface 310a which prevents reflection of external light on the surface thereof. The anti-glare treatment can be carried out by providing nanoscale surface roughness on the surface of the anti-reflection coating in an appropriate manner, e.g., by roughening the surface by ion-bombardment and plasma etching which may be performed in the chemical vapor deposition (CVD) system mentioned above. Specifically, electrons in the CVD system are accelerated by the electric field applied between the electrodes and collide inelastically with inert gas (e.g., Ar and/or He), reactive gas (e.g., N₂ and/or O₂) and highly corrosive gas (such as a halogen (e.g., Cl₂) or a halogen-source gas (e.g., CF₄, CF₂Cl₂)) to produce a complex mixture of reactive species which strike the surfaces that are in contact with them to form products that are volatile. Nanoscale surface roughness is achieved by a combination of partially directional surface bombardment by the positive ions produced from the inert gas and non-directional etching by the free radicals produced from the reactive gas and the corrosive gas. Preferably, the microstructure of the finished nanostructured surface 310a has a height variation in the range of about 50 nm to 100 nm.

Note that a substrate surface without the anti-reflection coating may be directly subjected to the aforementioned anti-glare treatment for reducing glare due to ambient light impinging thereon.

Although the invention has been explained in relation to its preferred embodiments, it is to be understood that many other possible modifications and variations can be made without departing from the spirit and scope of the invention as hereinafter claimed.

What is claimed is:

1. A process for manufacturing an anti-reflection coating of a predetermined thickness and uniformity on a substrate surface, the anti-reflection coating including at least a first and a second layer with different refractive index, the process comprising the steps of:
placing the substrate in a reaction chamber;
introducing a first reactive gas mixture into the reaction chamber;
generating a first free radical plasma within the reaction chamber by activating the first reactive gas mixture thereby forming the first layer on the substrate;
introducing a second reactive gas mixture into the reaction chamber; and
generating a second free radical plasma within the reaction chamber by activating the second reactive gas mixture thereby forming the second layer on the substrate.

2. The process as claimed in claim 1, wherein the first reactive gas mixture comprises gaseous oxygen or water vapor as well as a silicon-source precursor and the refractive index of the first layer is proportional to the ratio of the gaseous oxygen or water vapor to the silicon-source precursor in the first reactive gas mixture.

3. The process as claimed in claim 2, wherein the second reactive gas mixture comprises the gaseous oxygen or water vapor as well as the silicon-source precursor, and the ratio of the gaseous oxygen or water vapor to the silicon-source precursor in the second reactive gas mixture is different from that in the first reactive gas mixture.

4. The process as claimed in claim 2, wherein the second reactive gas mixture comprises gaseous water and a titanium-source precursor and the refractive index of the second layer is proportional to the ratio of the gaseous water to the titanium-source precursor in the second reactive gas mixture.

5. The process as claimed in claim 2, wherein the second reactive gas mixture comprises gaseous water and a tin-source precursor and the refractive index of the second layer is proportional to the ratio of the gaseous water to the tin-source precursor in the second reactive gas mixture.

6. The process as claimed in claim 1, wherein the substrate surface is a curved surface.

7. The process as claimed in claim 1, wherein the substrate surface has a plurality of concave or convex portions formed thereon.

8. The process as claimed in claim 7, wherein each of the concave or convex portions has a triangular cross section.

9. The process as claimed in claim 1, further comprising the step of providing nanoscale surface roughness on the surface of the anti-reflection coating.

10. The process as claimed in claim 9, wherein the nanoscale surface roughness is formed by ion-bombardment and plasma etching.

11. A process for reducing glare due to ambient light impinging upon a substrate surface by providing nanoscale surface roughness on the substrate surface.

12. The process as claimed in claim 11, wherein the nanoscale surface roughness is formed by ion-bombardment and plasma etching.
